(19) United States
(12) Patent Application Publication
(10) Pub. No.: US 2002/0084537 A1
(43) Pub. Date: Jul. 4, 2002

(54) System and method for packaging a semiconductor die

(76) Inventors: Johnny Cheng, Yung Ho City (TW); Joyce Hsu, Yung Ho City (TW)

Correspondence Address: TEXAS INSTRUMENTS INCORPORATED, P O BOX 655474, M/S 3999, DALLAS, TX, 75265

(21) Appl. No.: 09/752,904

(22) Filed: Dec. 28, 2000

(51) Int. Cl. H01L 23/48; H01L 23/52; H01L 29/40; H01L 21/44; H01L 21/48; H01L 21/50

(52) U.S. Cl. 257/784; 438/118; 438/127

(57) ABSTRACT

A system and method for packaging a semiconductor chip, the system comprising a semiconductor chip having a contact point, a top surface, and a bottom surface; a housing which encapsulates the top surface of the semiconductor chip wherein the bottom surface is unencapsulated; a pin having a top member encapsulated inside the housing and a protruding member extending outside the housing, the pin providing a conduit through which an electrical charge may travel; a bond wire electrically connected to the pin to the contact point on the semiconductor chip to provide an electrical path from the pin to the semiconductor chip; and a fixture having a matrix of cavities for receiving and supporting the protruding member of the pin during packaging. The system and method result in a packaged semiconductor device which is cost effective, results in smaller package dimensions, and reduces tooling lead-time and manufacturing costs.

### TECHNICAL FIELD OF THE INVENTION

This invention relates to the packaging of semiconductor dies and more particularly to a system and method for packaging a semiconductor die utilizing conductive pins.

### BACKGROUND OF THE INVENTION

The packaging of integrated circuits on a semiconductor die or chip requires processes which are both expensive and time consuming. In the semiconductor industry there is a continual push for smaller package sizes for integrated circuits. Thus, packaging may be further complicated and costly. Integrated circuit packages require designs and processes to connect the semiconductor die to external leads or pins and to encapsulate the semiconductor die, providing a housing for the die and protection from external elements. For example, these leads or pins may be contact balls attached to a substrate in a Ball Grid Array (BGA) package or a lead frame in a Quad Flat Package (QFP). The processes which utilize these types of packages result in the need for a housing in which the semiconductor die and the substrate or lead frame on which it is mounted are completely encapsulated. This increases the package height and is more costly because more material is utilized in the molding process and the process is further complicated. These packages must also provide a means for heat dissipation which further increases the costs associated with packaging a semiconductor die.

Furthermore, with the current use of lead frames in the packaging of some semiconductor dies, different die may need different designs of the substrate or the lead frame. Thus, it is costly to keep an adequate inventory of different substrate materials and lead frames to meet demand variation. In many instances more than one hundred types of lead frames and substrate materials are on hand. The tooling lead-time and manufacturing costs are also high due to the different dies requiring varying designs.

### SUMMARY OF THE INVENTION

These and other problems are generally solved or circumvented, and technical advantages are generally achieved, by preferred embodiments of the present invention. In accordance with a preferred embodiment of the present invention, a method for packaging a semiconductor die comprises loading a series of pins into a fixture having a top surface and a matrix of cavities for receiving and supporting the series of pins during the method for packaging. A packaged semiconductor device is formed by attaching the semiconductor die to the top surface of the fixture, the semiconductor die being adjacent to the series of pins, bonding the series of pins to contact points on the semiconductor die, and encapsulating the semiconductor die and the series of pins with an encapsulating material so that a portion of the pins extend outside of the encapsulating material. The encapsulated semiconductor die can then be removed from the fixture.

The method for packaging results in a semiconductor device which comprises, according to a preferred embodiment, a semiconductor die having a contact point, a top surface, and a bottom surface, a housing which encapsulates the top surface of the semiconductor die wherein the bottom surface is unencapsulated, and a pin having a top member encapsulated within the housing and a protruding member extending outside the housing whereby the pin provides a conduit through which an electrical charge may travel. The semiconductor device also comprises bond wire that is used to electrically connect to the pin and to the contact point on the semiconductor die to provide an electrical path from the pin to the semiconductor die.

One advantage of the preferred embodiment of the present invention is that it provides a less costly method of packaging a semiconductor die by eliminating costly lead frames and substrate and reducing the tooling and manufacturing costs.

Another advantage of the preferred embodiment of the present invention is that it results in a smaller package height as the substrate thickness is eliminated.

Yet another advantage of the preferred embodiment of the present invention is that it can be utilized to package semiconductor dies needing various pin counts. Thus, new design to market lead-time is shortened by eliminating lead frame or substrate tooling build up and manufacturing.

And another advantage of the preferred embodiment of the present invention is that it facilitates thermal conductivity for high power devices because the substrate is eliminated and ventilation is provided by exposing the semiconductor die to air.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 illustrates a cross section of a semiconductor device of the preferred embodiment of the present invention;

FIGS. 2a, 2b, and 2c illustrate various embodiments of the series of pins of the present invention;

FIG. 3 illustrates a preferred method of manufacturing the semiconductor device using a fixture of the present invention;

FIG. 4 is a top view of a preferred embodiment fixture of the present invention;

FIG. 5 illustrates the preferred embodiment of the present invention utilizing injection molding;

FIG. 6 illustrates the formation of mold flash;

FIG. 7 illustrates a preferred embodiment detachable collar of the present invention; and

FIG. 8 illustrates another embodiment of the pin of the present invention.

### DETAILED DESCRIPTION OF THE PRESENT INVENTION

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

With reference now to FIG. 1, there is shown a cross section of the packaged semiconductor device 10 of a preferred embodiment of the present invention. The semiconductor device 10 comprises a housing 12, a semiconductor die 14 having a top surface 11 and a bottom surface 13, a plurality of pins 16, and bond wires 18. The housing 12 is preferably formed from an injection molding process which utilizes any suitable commercial mold compound such as KMC288P. The housing 12 can be formed in any shape which is suitable for packaging a semiconductor die 14 and which encapsulates the top surface 11 of the semiconductor die 14 to protect the die 14 from external conditions. The bottom surface 13 is left unencapsulated providing several benefits including thermal conductivity and decreased package height as a housing substrate underneath the semiconductor die 14 is eliminated.

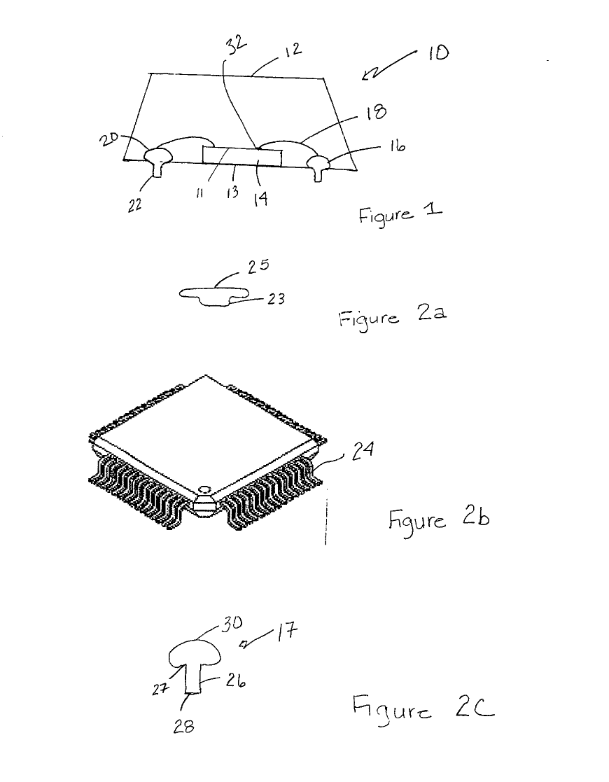

The plurality of pins 16 each comprise a top member 20 and an extending member 22 which is used as a lead for the packaged semiconductor device 10. The extending member 22 is of a form which conforms to the specifications of the application in which the semiconductor device 10 is to be used and allows the semiconductor device 10 to connect to other components, such as a printed circuit board or multi-chip modules. For example, as shown in FIGS. 2a and 2b, the plurality of pins 16 may be in the shape of a ball 23 having a cap 25 to be used in Ball Grid Array (BGA) type packages or in the shape of a lead 24 to be used in Quad Flat Pack ages/Small Outline Package (QFP/SO). The top member 20 is designed to provide an adequate surface for wire bonding the plurality of pins 16 to the semiconductor die 14.

A preferred embodiment mushroom pin 17 is shown in more detail in FIG. 2c. The mushroom pin 17 comprises a protruding member 26 having a substantially cylindrical shape and a first and second end 27 and 28, respectively. The mushroom pin 17 also includes a cap 30 integrally connected to the first end 27 whereby the first end 27 and cap 30 will be contained within the housing 12 (as shown in FIG. 1) after the injection molding process is completed. Also after completion of the injection molding process the second end 28 will extend outside of the housing 12 (shown in FIG. 1). The mushroom pin 17 is comprised of a metallic material or is coated in a metallic material such as, but not limited to, copper, gold, or Alloy 42 (which is an alloy of iron, cobalt & nickel). The shape of the mushroom pin 17 provides several advantages. First the top cap 30 provides a shape having sufficient area for providing a tight bond between the mushroom pin 17 and the commercial mold compound used to form the housing 12. Also the shape of the top cap 30 provides a means for reducing mold flash as will be explained below. However, It should be appreciated that other embodiments of the plurality of pins 16 may be utilized by the present invention. For example, pins having a protruding member which has a ball shape can be utilized for packages requiring such a design.

Referring back to FIG. 1, the bond wires 18 are any suitable commercial bond wire such as NMC-T1-24.3 and are used to connect the top member 20 of each of the plurality of pins 16 to contact points 32 (e.g. bond pads) on the semiconductor die 14. Once the top member 20 is connected to a contact point 32 on the semiconductor die 14, an electrical path is formed between the semiconductor die 14 and any circuitry which is externally connected to the semiconductor device 10 utilizing the plurality of pins 16.

FIG. 3 illustrates the preferred method of manufacturing the semiconductor device 10 (shown in FIG. 1) using a fixture 34. The fixture 34 comprises a plate 36 having an attachment region 38 and a matrix of cavities 40 defined within the plate 36. Generally, a fixture 34 will include a plurality of attachment regions 38 each substantially surrounded by a matrix of cavities 40 to allow for the simultaneous packaging of multiple semiconductor dies 14 utilizing the single fixture 34. The attachment region 38 is the location at which the semiconductor die 14 is seated during the packaging of the semiconductor device 10. The shape of the cavities 40 are designed to comply with the shape of the extending member 42 of the plurality of pins 16 to provide support for the extending member 42 during the packaging process.

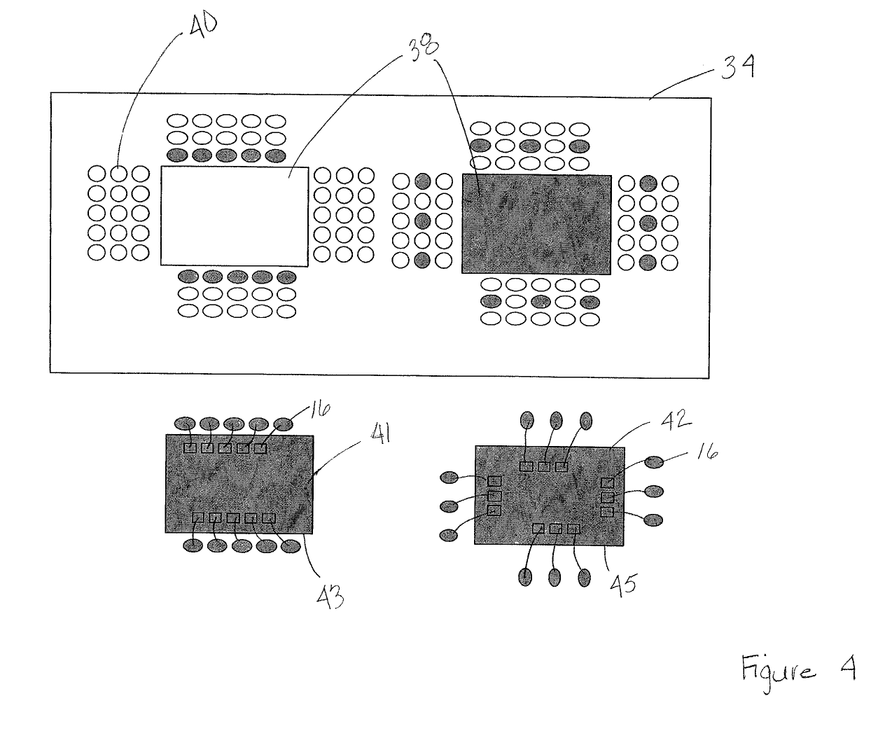

The matrix of cavities 40 are arranged to provide a generic pattern which enables the fixture 34 to be utilized to manufacture semiconductor devices 10 of various package configurations. The matrix of cavities 40 is designed to allow the proper placement of pins 16 for the various configurations having pins at different pitches. FIG. 4 is top view of an illustrative fixture 34.

The illustrative fixture 34 has two attachment regions 38 designed to simultaneously manufacture two semiconductor devices 10. However, it should be appreciated that the fixture 34 can be designed to simultaneously manufacture any number of semiconductor devices 10, preferably thirty to forty semiconductor devices 10. The matrix of cavities 40 is arranged on all sides of the semiconductor die 14 to facilitate manufacturing semiconductor devices 10 such as the quad flat package shown in FIG. 2b. Package configurations utilizing pins on fewer sides may also be produced utilizing the matrix of cavities 40. For instance, a package 41 having five pins 16 on each of two sides 43 may be manufactured utilizing the fixture 34 as shown in the left half of FIG. 4. Also a second package 42 having three pins 16 on each of four sides 45 may be manufactured utilizing the fixture 34 as shown in the right half of FIG. 4.

The matrix of cavities 40 are also designed to allow for the packaging of various semiconductor devices 10 having pins 16 with a wide range of pitches. Thus, a semiconductor device 10 having pins 16 with a 0.5 mm pitch can be produced as well as a semiconductor device 10 having pins with a one mm pitch. Furthermore, the matrix of cavities 40 are shown as adjacent rows, but it should be appreciated by those skilled in the art that the matrix of cavities 40 may consist of any pattern of cavities that would be suitable to manufacture the semiconductor devices 10.

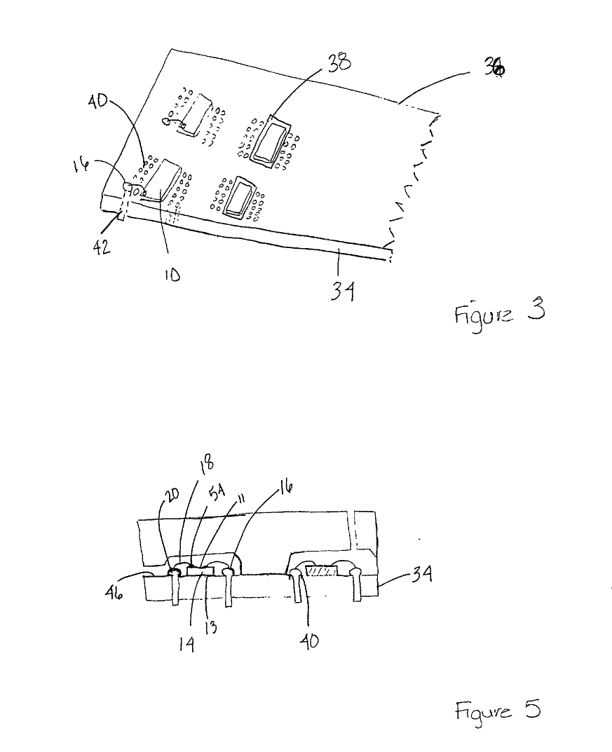

FIG. 5 illustrates the preferred embodiment of the present invention utilizing injection molding. In operation the process of packaging the semiconductor die 14 begins with loading the plurality of pins 16 into the fixture 34. Specifically, the plurality of pins 16 are loaded into the particular matrix of cavities 40 to obtain the desired pin configuration. Next, the semiconductor die 14 having a plurality of contact points 32 is attached to a top surface 46 of the fixture 34 utilizing an adhesive. The adhesive may be tape or an adhesive which can be easily removed. For example, tape having adhesive properties which are rendered inactive when exposed to ultra violet light may be used.

The top member 20 of each of the plurality of pins 16 is connected to the corresponding contact point 54 on the semiconductor die 14 utilizing the bond wires 18. The connecting process is preferably accomplished by ball bonding, but may be accomplished by any suitable method. The semiconductor die 14 and top member 20 are encapsulated to form a packaged semiconductor device. Encapsulation is generally accomplished by using a commercial molding process to form the housing. One skilled in the art will recognize that the fixture 34 can be incorporated into a typical injection mold die as illustrated in FIG. 5.

The housing is formed such that the top surface 11 containing the contact points are encapsulated. However, the bottom surface 13 is not encapsulated thus providing a higher level of thermal conductivity. This conductivity is achieved by the exposure of the bottom surface 13 which allows air to circulate on the semiconductor die 14 thus facilitating dissipation of the heat formed when the semiconductor die 14 is being operated. In other embodiments, the exposed semiconductor die 14 can be mounted directly onto a heat sink formed on the printed circuit board. This further facilitates packaging of high power devices. After the molding process described above is completed, the plurality of semiconductor devices 10 are singulated and removed from the fixture 34.

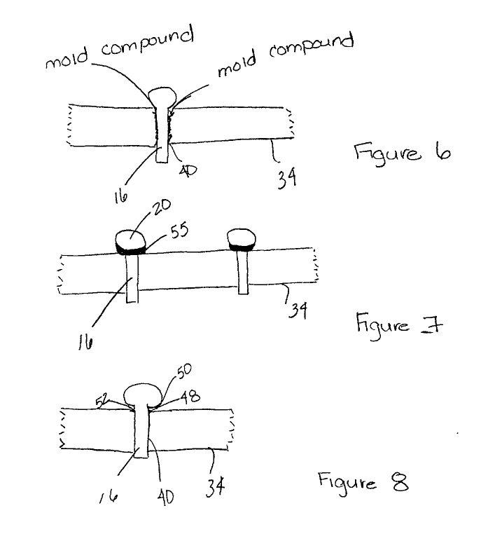

The process for packaging the semiconductor die 14 may further comprise steps which include affixing tape on the top surface of the fixture 34 before loading the series of pins into the fixture whereby mold flash is prevented. Mold flash may result when the housing 12 is being formed. Mold flash results when the molding compound is allowed to seep into the matrix of cavities 40 as shown in FIG. 6. If mold flash occurs, the semiconductor device 14 will have to be scrapped because either the plurality of pins 16 will not be able to be removed from the fixture 34 or they will be covered in the molding compound and not provide a sufficient conduit for the electrical charge.

As an alternative to the tape, a detachable collar 55 may be positioned around the plurality of pins 16, as shown in FIG. 7. The detachable collar 55 may be attached to the top member 20 of the plurality of pins 16 before bonding of the plurality of pins 16 to the semiconductor die 14 to prevent mold flash.

FIG. 8 shows yet another alternate embodiment that should help prevent mold flash. In this embodiment, each of the plurality of pins 16 is designed with a groove 48 around a neck 50. The groove 48 forms a space 52 in which the commercial mold compound may be trapped if the compound flows pass the top surface of the fixture 34 into the cavities 40.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A semiconductor device comprising:
a semiconductor chip having a contact point, a top surface, and a bottom surface;
a housing which encapsulates the top surface of the semiconductor chip wherein the bottom surface is unencapsulated;
a pin having a top member encapsulated within the housing and a protruding member extending outside the housing, the pin providing a conduit through which an electrical charge may travel; and
a bond wire electrically connected to the pin and to the contact point on the semiconductor chip to provide an electrical path from the pin to the semiconductor chip.

2. The device as in claim 1 wherein the pin is a mushroom pin having a top cap and a protruding member having a substantially cylindrical shape.

3. The device as in claim 2 wherein the protruding member has a substantially ball shape.

4. The device as in claim 1 wherein the pin comprises a metallic material.

5. The device as in claim 4 wherein the metallic material is gold, alloy 42 or copper.

6. The device as in claim 1 wherein the housing comprises a plastic material.

7. The device as in claim I wherein the housing is produced using an injection mold.

8. A system for packaging a semiconductor chip, the system comprising:
a semiconductor chip having a contact point, a top surface, and a bottom surface;
a housing which encapsulates the top surface of the semiconductor chip wherein the bottom surface is unencapsulated;
a pin having a top member encapsulated within the housing and a protruding member extending outside the housing, the pin providing a conduit through which an electrical charge may travel;
a bond wire electrically connected to the pin and to the contact point on the semiconductor chip to provide an electrical path from the pin to the semiconductor chip; and
a fixture having a matrix of cavities for receiving and supporting the protruding member of the pin during packaging.

9. The system as in claim 8 wherein the matrix of cavities has a pitch determined by the type of semiconductor chip.

10. The system as in claim 8 wherein the pin is a mushroom pin having a top cap and a protruding member having a substantially cylindrical shape.

11. The system as in claim 8 wherein the top member of the pin has a shape which is greater in width than the width of the cavities whereby the top member blocks entrance of any element into the cavities.

12. The system as in claim 8 wherein the pin comprises a metallic material.

13. The system as in claim 12 wherein the metallic material is gold, copper, or alloy 42.

14. The package as in claim 8 wherein the housing comprises a plastic material.

15. The system as in claim 8 wherein the fixture further comprises an attachment region wherein the semiconductor chip is secured during packaging.

16. A method for packaging a semiconductor chip, the method comprising:
loading a series of pins into a fixture having a top surface and a matrix of cavities for receiving and supporting the series of pins during the process for packaging;
attaching the semiconductor chip to the top surface of the fixture, the semiconductor chip being adjacent to the series of pins;
bonding the series of pins to contact points on the semiconductor chip;
encapsulating the semiconductor chip and the series of pins with an encapsulating material so that a portion of the pins extend outside of the encapsulating material to form a packaged semiconductor device; and
removing the encapsulated semiconductor chip from the fixture.

17. The method as in claim 16 and further comprising affixing tape on the top surface of the fixture before loading the series of pins into the fixture.

18. The method as in claim 16 and further comprising affixing a detachable collar around the series of mushroom pins before bonding the series of pins to the contact points.

19. The method as in claim 16 wherein the series of pins are mushroom pins having a top cap and protruding member having a substantially cylindrical shape.

20. The method as in claim 16 wherein the bonding comprises bonding the top cap to the contact points on the semiconductor chip.

21. The method as in claim 16 wherein the encapsulating comprises encapsulating only the top surface of the semiconductor chip.

22. The method as in claim 16 wherein the encapsulating material is plastic.
